(19) United States
(12) Patent Application Publication
(10) Pub. No.: US 2006/0114716 A1
(43) Pub. Date: Jun. 1, 2006

(54) Magnetoresistance element, magnetic memory, and magnetic head

(76) Inventors: Tadashi Kai, Kawasaki-shi (JP); Toshihiko Nagase, Sagamihara-shi (JP); Tatsuya Kishi, Yokohama-shi (JP); Yoshiaki Saito, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/335,468

(22) Filed: Jan. 20, 2006

Related U.S. Application Data
(63) Continuation of application No. 10/689,621, filed on Oct. 22, 2003.

(30) Foreign Application Priority Data
Oct. 25, 2002 (JP) 2002-311497

(51) Int. Cl. G11C 11/00

(52) U.S. Cl. 365/158; 365/171

(57) ABSTRACT

There is provided a magnetoresistance element including a free layer that includes a first ferromagnetic layer and a second ferromagnetic layer whose magnetization directions are equal to each other and a nonmagnetic film intervening between the first and second ferromagnetic layers, a pinned layer including a third ferromagnetic layer that faces the free layer, and a nonmagnetic layer intervening between the free layer and the pinned layer, the nonmagnetic film containing a material selected from the group including titanium, vanadium, zirconium, niobium, molybdenum, technetium, hafnium, tungsten, rhenium, alloys thereof, semiconductors and insulators.

### CROSS-REFERENCE TO RELATED APPLICATIONS

This application is a Continuation of U.S. patent application Ser. No. 10/689,621, filed Oct. 22, 2003, and is based upon and claims the benefit of priority from the prior Japanese Patent Application No. 2002-311497, filed Oct. 25, 2002. The entire contents of these applications are incorporated herein by reference.

### BACKGROUND OF THE INVENTION

1. Field of the Invention

The present invention relates to a magneto-resistance element, a magnetic memory, and a magnetic head.

2. Description of the Related Art

The magnetoresistance element has a laminate structure including a pair of ferromagnetic layers and a nonmagnetic layer interposed between these ferromagnetic layers. The resistance value of the magnetoresistance element is changed in accordance with the direction of magnetization of one ferromagnetic layer relative to the magnetization of the other ferromagnetic layer. The magnetoresistance element exhibiting the particular magnetoresistance effect can be used in various fields. For example, the magnetoresistance element can be used in a magnetic random access memory (MRAM).

In the MRAM, the memory cell includes the magnetoresistance element, and the information is stored by using one ferromagnetic layer as a pinned layer in which the direction of magnetization is not changed on applying a magnetic field, and the other ferromagnetic layer as a free layer in which the direction of magnetization can be changed on applying the magnetic field. In other words, in writing information, a synthetic magnetic field generated by passing a current pulse through each of the word line and the bit line is allowed to act on the magneto-resistance layer. As a result, the magnetization of the free layer is changed between the state that the magnetization of the free layer is directed like the magnetization of the pinned layer and the state that the magnetization of the free layer is directed in the opposite direction. In this fashion, the binary information of “0” and “1” is stored in the memory cell in accordance with these two states.

When the written information is read out, an electric current is allowed to flow through the magnetoresistance element. Since the resistance of the magnetoresistance element in one of the two states noted above differs from that in the other state, it is possible to read out the information stored in the memory cell by, for example, detecting the flowing current.

For achieving a high degree of integration of the MRAM, it is highly effective to decrease the area of the magnetoresistance element. It should be noted in this connection that, if the area of the free layer is decreased, the coercive force of the free layer is increased. As a result, it is necessary to increase the intensity of the magnetic field required for causing the magnetization of the free layer to be changed between the state that the magnetization of the free layer is directed like the magnetization of the pinned layer and the state that the magnetization of the free layer is directed in the opposite direction, i.e., the intensity of the switching magnetic field, in accordance with the decrease in the area of the magnetoresistance element.

It is possible to increase the intensity of the switching magnetic field by, for example, passing a larger current through the write wiring in writing information. In this case, however, the power consumption is increased. In addition, the life of the wiring is shortened. It follows that it is of high importance to develop a magnetoresistance element capable of reversing the magnetization of the free layer with a weak magnetic field.

It is possible to use as the free layer a laminate structure including a plurality of ferromagnetic layers and a nonmagnetic layer interposed between the adjacent ferromagnetic layers. In this case, it is possible for the free layer to employ the construction that ferromagnetic layers form an antiferromagnetic exchange coupling, i.e., the construction that the adjacent ferromagnetic layers are rendered opposite to each other in the direction of magnetization.

For example, it is disclosed in Japanese Patent Disclosure No. 9-251621 that, in order to obtain a high output voltage in reading out the written information, the free layer is formed of a pair of ferromagnetic layers and a nonmagnetic film interposed between the ferromagnetic layers, and that these ferromagnetic layers are allowed to form an antiferromagnetic exchange coupling. Incidentally, a nonmagnetic metal such as copper, gold, silver, chromium, ruthenium or aluminum is used for forming the nonmagnetic film in this literature.

Japanese Patent Disclosure No. 2001-156358 teaches that, in order to lower the switching magnetic field, employed is a magnetoresistance element having a laminate structure represented by a first antiferromagnetic layer/a first ferromagnetic layer/a first tunneling insulation layer/a second ferromagnetic layer/a first nonmagnetic film/a third ferromagnetic layer/a second nonmagnetic film/a fourth ferromagnetic layer/a second tunneling insulation film/a fifth ferromagnetic layer/a second antiferromagnetic layer. In the structure, the second and third ferromagnetic layers form an antiferromagnetic exchange coupling, and the third and fourth ferromagnetic layers form an antiferromagnetic exchange coupling. Incidentally, copper, gold, silver, chromium, ruthenium, iridium, aluminum or an alloy thereof is used for forming each of the first and second nonmagnetic films in this literature.

Further, it is disclosed in Japanese Patent Disclosure No. 2002-151758 that, in order to increase the stability against the thermal fluctuation, the free layer is formed to have a structure in which a ferromagnetic layer and an intermediate layer are laminated one upon the other at least five times and each two adjacent ferromagnetic layers form an antiferromagnetic exchange coupling. In this literature, chromium, ruthenium, rhodium, iridium, rhenium or an alloy thereof is used as a material of the intermediate layer.

### BRIEF SUMMARY OF THE INVENTION

According to a first aspect of the present invention, there is provided a magnetoresistance element comprising a free layer comprising a first ferromagnetic layer and a second ferromagnetic layer that face each other and whose magnetization directions are equal to each other and a nonmagnetic film intervening between the first and second ferromagnetic layers, the free layer being changeable in the magnetization directions on applying a magnetic field, a first pinned layer comprising a third ferromagnetic layer that faces the free layer, the first pinned layer retaining a magnetization direction thereof on applying the magnetic field, and a first nonmagnetic layer intervening between the free layer and the first pinned layer, the nonmagnetic film being made of a material selected from the group consisting of titanium, vanadium, zirconium, niobium, molybdenum, technetium, hafnium, tungsten, rhenium and alloys thereof.

According to a second aspect of the present invention, there is provided a magnetoresistance element comprising a free layer comprising a first ferromagnetic layer and a second ferromagnetic layer that face each other and whose magnetization directions are equal to each other and a nonmagnetic film intervening between the first and second ferromagnetic layers, the free layer being changeable in the magnetization directions on applying a magnetic field, a first pinned layer comprising a third ferromagnetic layer that faces the free layer, the first pinned layer retaining a magnetization direction thereof on applying the magnetic field, and a first nonmagnetic layer intervening between the free layer and the first pinned layer, a material of the nonmagnetic film being semiconductor or insulator.

According to a third aspect of the present invention, there is provided a magnetoresistance element comprising a free layer comprising a first ferromagnetic layer and a second ferromagnetic layer that face each other and whose magnetization directions are equal to each other and a nonmagnetic film intervening between the first and second ferromagnetic layers, the free layer being changeable in the magnetization directions on applying a magnetic field, a first pinned layer comprising a third ferromagnetic layer that faces the free layer, the first pinned layer retaining a magnetization direction thereof on applying the magnetic field, and a first nonmagnetic layer intervening between the free layer and the first pinned layer, the nonmagnetic film containing a material selected from the group consisting of titanium, vanadium, zirconium, niobium, molybdenum, technetium, hafnium, tungsten, rhenium, alloys thereof, semiconductors and insulators.

According to a fourth aspect of the present invention, there is provided a magnetic memory comprising a word line, a bit line intersecting the word line, and a memory cell positioned in an intersection portion of the word and bit lines and including the magnetoresistance element according to any of the first to third aspects.

According to a fifth aspect of the present invention, there is provided a magnetic head comprising the magnetoresistance element according any of the first to third aspects, and a support member supporting the magnetoresistance element.

### BRIEF DESCRIPTION OF THE SEVERAL VIEWS OF THE DRAWING

FIG. 1 is a cross-sectional view schematically showing a magnetoresistance element according to an embodiment of the present invention;

FIG. 2 is a graph showing the relationship between the exchange coupling constant J and the switching magnetic field obtained in respect of the magnetoresistance element shown in FIG. 1;

FIG. 3 is an oblique view schematically showing an MRAM using the magnetoresistance element shown in FIG. 1;

FIG. 4 is an oblique view schematically showing a magnetic head assembly that includes a magnetic head using the magnetoresistance element shown in FIG. 1;

FIG. 5 is an oblique view schematically showing a magnetic recording-reproducing apparatus in which the magnetic head assembly shown in FIG. 4 is mounted;

FIG. 6 is a cross-sectional view schematically showing a magnetoresistance element according to Example 1 of the present invention;

FIG. 7 is a graph showing the switching magnetic field for the magnetoresistance element according to each of Example 1, Comparative Example 1, and Comparative Example 2;

FIG. 8 is a graph showing the switching magnetic field for the magnetoresistance element according to Example 2;

FIG. 9 is a cross-sectional view schematically showing a magnetoresistance element according to Example 3 of the present invention;

FIG. 10 is a graph showing the switching magnetic field for the magnetoresistance element according to Example 3;

FIG. 11 is a graph showing the MR ratio of the magnetoresistance element according to Example 3;

FIG. 12 is a cross-sectional view schematically showing a magnetoresistance element according to Example 4 of the present invention; and

FIG. 13 is a graph showing the switching magnetic field for the magnetoresistance element according to Example 4.

### DETAILED DESCRIPTION OF THE INVENTION

An embodiment of the present invention will now be described with reference to the accompanying drawings. In the accompanying drawings, the constituting elements performing the same or similar functions are denoted by the same reference numerals so as to omit the overlapping description.

Incidentally, the phrase “ferromagnetic layers are equal to each other in the direction of magnetization” means the state that the magnetizations of the ferromagnetic layers make an acute angle with each other, and typically means the state that the magnetization directions of the ferromagnetic layers are equal to each other substantially completely. On the other hand, the phrase “ferromagnetic layers are opposite to each other in the direction of magnetization” means the state that the magnetizations of the ferromagnetic layers make an obtuse angle with each other, and typically means the state that the magnetization directions of the ferromagnetic layers are substantially parallel and opposite to each other. Further, the magnetic structure of the ferromagnetic layer included in the magnetoresistance element can be examined by using an MFM (Magnetic Force Microscope) or a spin-resolved SEM (Scanning Electron Microscope) under the state that the ferromagnetic layer is exposed to the outside. Also, the expression “alloys thereof” used in each of the first and third aspects denotes the alloys containing at least one of the aforementioned metals, and typically denotes the alloys containing at least two of the aforementioned metals.

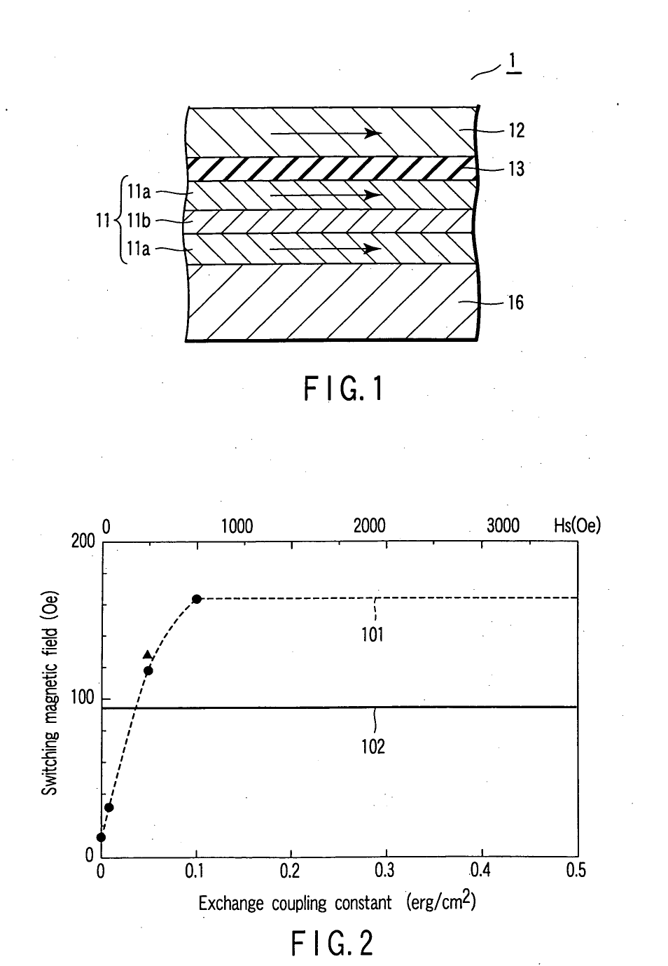

FIG. 1 is a cross-sectional view schematically showing a magnetoresistance element 1 according to an embodiment of the present invention. As shown in the drawing, the magnetoresistance element 1 includes a free layer 11, a pinned layer 12 positioned to face the free layer 11, and a nonmagnetic layer 13 interposed between the free layer 11 and the pinned layer 12. Incidentally, a reference numeral 16 shown in the drawing denotes a lower electrode.

The free layer 11 includes a pair of ferromagnetic layers 11a and a nonmagnetic film 11b interposed between the two ferromagnetic layers 11a. The magnetization of each of these two ferromagnetic layers 11a is directed to the right in the drawing as denoted by arrows.

In this embodiment, a material having a small number of valence electrons or a material that does not have a conduction electron at all is used as a material of the nonmagnetic film 11b. In the case of using such a material for forming the nonmagnetic film 11b, it is possible to reverse the magnetization of the free layer 11 with a relatively weak magnetic field. The reason for this is considered to be as follows, though it is not desired to be restricted by the theory.

FIG. 2 is a graph showing the relationship between the exchange coupling constant J and the switching magnetic field obtained in respect of the magneto-resistance element shown in FIG. 1. In the graph of FIG. 2, the exchange coupling constant J between the two ferromagnetic layers 11a is plotted on the abscissa, and the switching magnetic field is plotted on the ordinate. Also, a curve 101 shown in FIG. 2 denotes the data obtained in respect of the magneto-resistance element 1 shown in FIG. 1, and a straight line 102 denotes the data obtained in respect of the magnetoresistance element 1 in which the free layer 11 is formed of a single ferromagnetic layer 11a alone.

Incidentally, the data given in FIG. 2 were obtained by LLG (Landau-Lifshitz-Gilbert) simulation under the conditions given below. Specifically, the magnetoresistance element 1 was assumed to have a rectangular planar shape sized at 0.24 μm×0.48 μm. The thickness of each of the ferromagnetic layers 11a was set at 2 nm, and the thickness of the nonmagnetic film 11b was set to fall within a range of between 1 nm and 1.5 nm. Also, the exchange coupling constant J of the ferromagnetic layer 11a was changed in accordance with the thickness of the nonmagnetic film 11b. Further, the uniaxial anisotropy Kᵤ of the ferromagnetic layer 11a was set at 1×10⁴ erg/cc, and the saturation magnetization Ms of the ferromagnetic layer 11a was set at 1400 emu/cc.

In the magnetoresistance element 1 in which a laminate structure of the ferromagnetic layer 11a/nonmagnetic film 11b/ferromagnetic layer 11a is employed in the free layer 11, it is possible to diminish the switching magnetic field by setting small the exchange coupling constant J, i.e., by weakening the exchange coupling between the two ferromagnetic layers 11a as shown in FIG. 2.

It is certainly possible to weaken the exchange coupling between the two ferromagnetic layers 11a by increasing the thickness of the nonmagnetic film 11b. However, it is advantageous for the thickness of the nonmagnetic film 11b to be small in view of the magnetoresistance ratio (MR ratio). Therefore, in order to realize simultaneously both a high MR ratio and a sufficiently small switching magnetic field, it is required for the nonmagnetic film 11b to be thin and for the exchange coupling between the two ferromagnetic layers 11a to be sufficiently weak.

The exchange coupling between the two ferromagnetic layers 11a is derived from the RKKY interaction. The RKKY interaction is the exchange interaction acting between the spins through the conduction electron. Therefore, under the condition that the nonmagnetic film 11b has a prescribed thickness, the exchange coupling constant J is rendered small in the case of using a metal having a smaller number of valence electrons as the material of the nonmagnetic film 11b. Also, in the case of using a material that does not have a conduction electron at all as a material of the nonmagnetic film 11b, it is possible to render zero the exchange coupling constant J.

Such being the situation, in the case of using a metal having a smaller number of valence electrons as the material of the nonmagnetic film 11b, it is possible to sufficiently weaken the exchange coupling between the two ferromagnetic layers 11a even in the case where the nonmagnetic film 11b is rendered thin. Also, in the case of using a material that does not have a conduction electron at all as the material of the nonmagnetic film 11b, it is possible to cut off the exchange coupling between the two ferromagnetic layers 11a regardless of the thickness of the nonmagnetic film 11b.

In addition, in the present embodiment, the two ferromagnetic layers 11a are equal to each other in the direction of magnetization. Where the two ferromagnetic layers 11a are opposite to each other in the direction of magnetization, the switching of the magnetization cannot be performed sharp, and the shape of the asteroid curve is deteriorated. On the other hand, where the two ferromagnetic layers 11a are equal to each other in the direction of magnetization, the magnetization can be switched sharp, and the squareness ratio is improved. Further, the shape of the asteroid curve is rendered satisfactory.

Under the circumstances, according to the present embodiment, it is possible to achieve a high MR ratio. In addition, it is possible to reverse the magnetization of the free layer 11 with a relatively weak magnetic field.

Incidentally, in the case of using a material that does not have a conduction electron at all for forming the nonmagnetic film 11b, it is possible to cut off the exchange coupling between the two ferromagnetic layers 10a regardless of the thickness of the nonmagnetic film 11b, as described above. In this case, the force for restricting the direction of magnetization is not exerted between the two ferromagnetic layers 11a and, thus, the magnetization directions of the ferromagnetic layers 11a are changed in accordance with the direction of the external magnetic field. Since it is impossible for the direction of the magnetic field applied to one of the two ferromagnetic layers 11a to be opposite to that of the magnetic field applied to the other ferromagnetic layer 11a, the two ferromagnetic layers 11a always retain the state that the magnetization directions of the ferromagnetic layers 11a are equal to each other.

The materials that can be used for manufacturing the magnetoresistance element 1 shown in FIG. 1 will now be described.

The ferromagnetic layer 11a included in the free layer 11 can be made of, for example, Fe, Co, Ni, alloys thereof and Heusler alloys such as the NiMnSb series alloys, PtMnSb series alloys and CO₂MnGe series alloys. It is desirable for the ferromagnetic layer 11a to have an average thickness which permits forming the ferromagnetic layer 11a as a continuous film and which is so small that a switching magnetic field with an excessively high intensity is not necessary. It is desirable for the average thickness of the ferromagnetic layer 11a to fall generally within a range of between 0.1 nm and 100 nm, and preferably within a range of between 1 nm and 10 nm.

The nonmagnetic film 11b included in the free layer 11 can be made of, for example, Ti, V, Zr, Nb, Mo, Tc, Hf, W, Re and alloys thereof. Among the metals and the alloys referred to above, it is desirable to use Ti, V, Zr, Nb, Mo, Tc, Hf, W and alloys thereof, and it is more desirable to use Nb, Mo, Tc and alloys thereof for forming the nonmagnetic film 11b in view of the solid-state electron theory.

It is also possible to use a semiconductor or an insulator as a material of the nonmagnetic film 11b included in the free layer 11. The semiconductors that can be used for forming the nonmagnetic film 11b include, for example, Si and Ge. On the other hand, the insulators that can be used for forming the nonmagnetic film 11b include, for example, Al₂O₃ and SiO₂.

Where the metal or the alloy thereof is used for forming the nonmagnetic film 11b, it is desirable for the nonmagnetic film 11b to have an average thickness which permits forming the nonmagnetic film 11b as a continuous film and which also permits sufficiently decreasing the exchange coupling constant J. Such being the situation, it is desirable for the average thickness of the nonmagnetic film 11b to be not smaller than 0.1 nm and to be not larger than 10 nm.

Where a semiconductor material or an insulator material is used for forming the nonmagnetic film 11b, it is possible to cut off the exchange coupling between the two ferromagnetic layers 10a even if the nonmagnetic film 11b has a small average thickness. It follows that, in this case, it is desirable for the average thickness of the nonmagnetic film 11b to be small as far as it is possible to form the nonmagnetic film 11b as a continuous film. To be more specific, it is desirable for the average thickness of the nonmagnetic film 11b to fall within a range of between 0.1 nm and 10 nm.

It should also be noted that, if the nonmagnetic film 11b has a small average thickness, it is possible to realize a high MR ratio. Such being the situation, it is desirable for the average thickness of the nonmagnetic film 11b to be not larger than 5 nm.

Incidentally, in the present embodiment, the free layer 11 has a three-layer structure including the two ferromagnetic layers 11a. However, it is also possible for the free layer 11 to include a larger number of ferromagnetic layers 11a. For example, it is possible for the free layer 11 to have a five-layer structure including three ferromagnetic layers 11a and two nonmagnetic films 11b interposed between the adjacent ferromagnetic layers 11a.

It is possible for the pinned layer 12 to be formed of a ferromagnetic layer alone or to be formed of a plurality of ferromagnetic layers and a nonmagnetic layer interposed between the adjacent ferromagnetic layers. The materials exemplified previously in conjunction with the ferromagnetic layer 12a can also be used for forming, for example, the ferromagnetic layer included in the pinned layer 12. Also, the materials exemplified previously in conjunction with the nonmagnetic film 11b can also be used for forming the nonmagnetic film included in the pinned layer 12. In addition, it is also possible to use, for example, Cu, Au, Ag, Cr, Ru, Ir, Al and alloys thereof for forming the nonmagnetic film included in the pinned layer 12.

The nonmagnetic layer 13 can be made of, for example, dielectric materials or insulating materials such as Al₂O₃, SiO₂, MgO, AlN, AlON, GaO, Bi₂O₃, SrTiO₂ and AlLaO₃. In this case, it is possible for the magnetoresistance element 1 to be a ferromagnetic tunneling junction element or an MTJ (Magnetic Tunneling Junction) element. Also, the nonmagnetic layer 13 can be made of a conductive material such as Cu, Ag or Au. In this case, it is possible for the magnetoresistance element 1 to be a giant magneto-resistance (MGR) element utilizing the spin dependency of the conduction electron scattering at the interface.

Incidentally, where the magnetoresistance element 1 is an MTJ element, the value of the tunnel current flowing between the free layer 11 and the pinned layer 12 is proportional to the cosine of the angle made between the direction of magnetization of the free layer 11 and the direction of magnetization of the pinned layer 12. In other words, the tunnel resistance is allowed to have the smallest value under the state that the direction of magnetization of the free layer 11 is opposite to the direction of magnetization of the pinned layer 12. Also, the tunnel resistance is allowed to have the largest value under the state that the direction of magnetization of the free layer 11 is equal to the direction of magnetization of the pinned layer 12.

Also, where the magnetoresistance element 1 is a GMR element, the resistance value is proportional to the cosine of the angle made between the direction of magnetization of the free layer 11 and the direction of magnetization of the pinned layer 12. The resistance is allowed to have the smallest value under the state that the direction of magnetization of the free layer 11 is opposite to the direction of magnetization of the pinned layer 12. Also, the resistance is allowed to have the largest value under the state that the direction of magnetization of the free layer 11 is equal to the direction of magnetization of the pinned layer 12.

It is possible for the magnetoresistance element 1 to further include an antiferromagnetic layer on the pinned layer 12. In the case of forming the antiferromagnetic layer, the magnetization of the pinned layer can be fixed more strongly by the exchange coupling between the pinned layer 12 and the antiferromagnetic layer. The antiferromagnetic layer can be made of, for example, an alloy such as Fe—Mn, Pt—Mn, Pt—Cr—Mn, Ni—Mn or Ir—Mn as well as NiO. It is also possible to form a hard magnetic layer in place of the antiferromagnetic layer on the pinned layer 12. In this case, the magnetization of the pinned layer 12 can be fixed more strongly by the fringing field from the hard magnetic layer.

The magnetoresistance element 1 shown in FIG. 1 has a laminate structure in which the free layer 11, the nonmagnetic layer 13 and the pinned layer 12 are successively formed on the lower electrode 16. However, it is also possible for the magnetoresistance element 1 to have another structure. For example, it is possible to obtain the magnetoresistance element 1 by successively forming the pinned layer 12, the nonmagnetic layer 13 and the free layer 11 on the lower electrode 16. It is also possible for magneto-resistance element 1 to have a structure in which the free layer 11 is interposed between a pair of pinned layers 12 and a pair of nonmagnetic layers 13 are interposed between one of the pinned layers 12 and the free layer 11 and between the other pinned layer 12 and the free layer 11, respectively.

It is possible for the magnetoresistance element 1 to further include, for example, a protective layer (not shown) in addition to the lower electrode 16. Each of the lower electrode 16 and the protective layer can be formed of a layer containing, for example, Ta, Ti, Pt, Pd or Au, or formed of a laminate film represented by Ti/Pt, Ta/Pt, Ti/Pd, Ta/Pd or Ta/Ru. Also, it is possible for the magnetoresistance element 1 to further comprise an underlayer for enhancing the crystal orientation of each layer constituting the free layer 11, the pinned layer 12, etc. The known material such as NiFe can be used for forming the underlayer.

The magnetoresistance element 1 can be obtained, for example, by successively forming various kinds of thin films on the underlayer formed on one main surface of a substrate. These thin films can be formed by vapor deposition methods such as sputtering method, evaporation method and the molecular beam epitaxy as well as by the combination of the vapor deposition method and the oxidation method and/or nitriding method. Also, it is possible to use a substrate made of, for example, Si, SiO₂, Al₂O₃, spinel, or AlN.

It is possible for the magnetoresistance element 1 to have various planar shapes. For example, it is possible for the magnetoresistance element 1 to have a rectangular planar shape, a parallelogrammatic planar shape, a rhombic planar shape, or a polygonal planar shape having at least 5 corners. Also, it is possible for the edge portion of the magnetoresistance element 1 to be elliptical. The parallelogrammatic or rombic magnetoresistance element 1 can be manufactured easily and is advantageous in decreasing the switching magnetic field, compared with the magnetoresistance element 1 of other shapes.

The magnetoresistance element 1 described above can be used in various fields. First of all, an MRAM using the magnetoresistance element 1 described above will now be described.

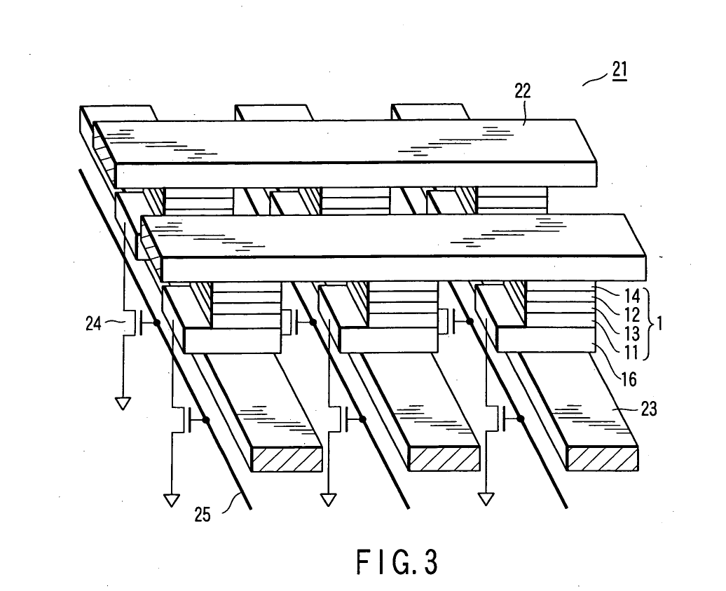

FIG. 3 is an oblique view schematically showing an MRAM using the magnetoresistance element 1 shown in FIG. 1. The MRAM 21 shown in FIG. 3 includes the magnetoresistance elements 1 that are arranged to form a matrix. In each of these magnetoresistance elements 1, an antiferromagnetic layer 14 is formed on the pinned layer 12.

The MRAM 21 further includes bit lines 22 and writing word lines 23 intersecting the bit lines 22. Each of the magnetoresistance elements 1 is interposed between the bit line 22 and the word line 23.

The bit line 22 serves to electrically connect the antiferromagnetic layers 14 included in the magnetoresistance elements 1 positioned adjacent to each other in the lateral direction in the drawing. The word line 23 is positioned to face the magneto-resistance elements 1 positioned adjacent to each other in the vertical direction in the drawing. Also, the word line 23 is electrically insulated from each of the magnetoresistance elements 1.

The MRAM 21 further includes transistors 24 and reading word lines 25. One of the source and drain of the transistor 24 is electrically connected to the free layer 11 of the magnetoresistance element 1 via the lower electrode 16. In the MRAM 21, a single magnetoresistance element and a single transistor collectively form a memory cell. Also, the word line 25 electrically connect the gates of the transistors 24 arranged in the vertical direction in the drawing.

When information is written in the MRAM 21, write currents are allowed to flow through a single bit line 22 and a single word line 23 positioned to face a certain magnetoresistance element 1, and the synthetic magnetic field generated by the write currents is allowed to act on the magnetoresistance element 1. The free layer 11 included in the magnetoresistance element 1 reverses or retains the direction of magnetization thereof in accordance with the direction of the current flowing through the bit line 22. Information is written in this fashion.

Also, when the information written in the MRAM 21 is read out, the bit line 22 positioned to face a certain magnetoresistance element 1 is selected. At the same time, a prescribed voltage is applied to the word line 25 corresponding to the particular magnetoresistance element 1 so as to render conductive the transistor 24 connected to the particular magneto-resistance element 1. The resistance value of the magnetoresistance element 1 in the case where the direction of magnetization of the free layer 11 is equal to the direction of magnetization of the pinned layer 12 differs from that in the case where the direction of magnetization of the free layer 11 is opposite to the direction of magnetization of the pinned layer 12. Therefore, it is possible to read out the information stored in the magnetoresistance element 1 by detecting under the particular state the current flowing between the bit line 22 and the lower electrode 16 by using a sense amplifier.

In the MRAM 21 shown in FIG. 3, it is possible to select the magnetoresistance element 1 by using the transistor 24. Alternatively, it is also possible to select the magnetoresistance element 1 by using another switching element such as a diode. In the case of using, for example, a diode, it is possible to utilize the word line 23 for both the writing operation and the reading operation if the magnetoresistance element 1 and the diode are connected in series between the word line 23 and the bit line 22, with the result that the word line 25 is rendered unnecessary in addition to the transistor 24.

Where the memory cell is formed of a single magnetoresistance element 1 and a single switching element as described above, it is possible to achieve a nondestructive read. Incidentally, in carrying out a destructive read, it is possible for the memory cell not to include a switching element.

A magnetic recording-reproducing apparatus using the magnetoresistance element 1 described above will now be described.

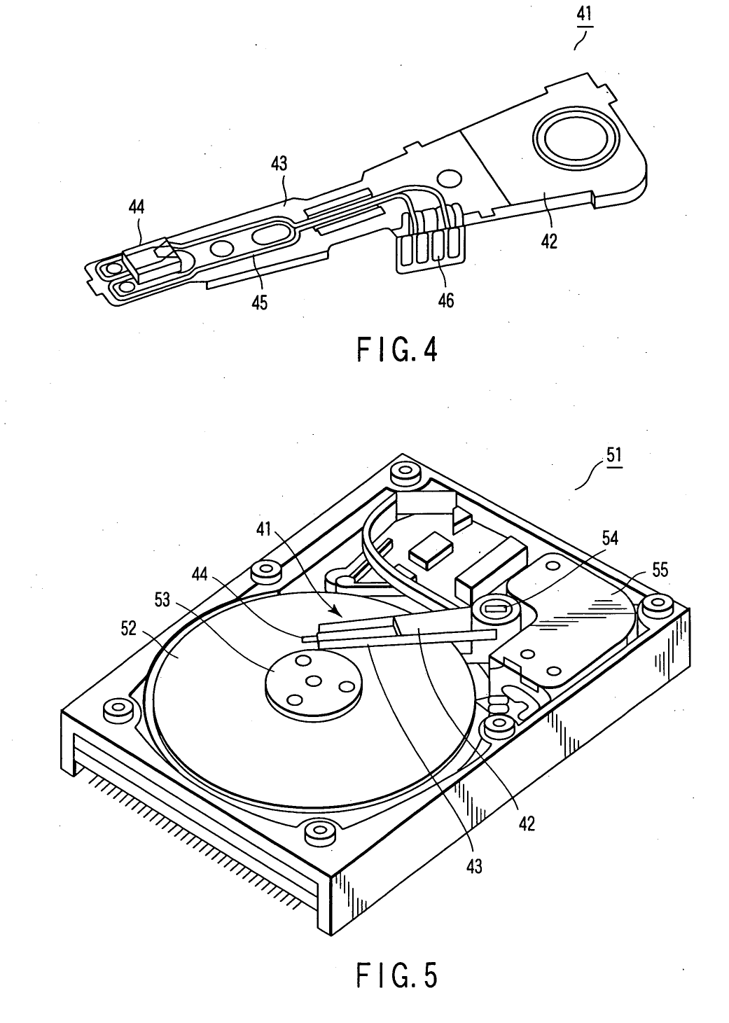

FIG. 4 is an oblique view schematically showing a magnetic head assembly 41 including a magnetic head that uses the magnetoresistance element 1 shown in FIG. 1. The magnetic head assembly 41 shown in FIG. 4 includes an actuator arm 42 provided with, for example, a bobbin portion for holding the driving coil. One end of a suspension 43 is mounted to the actuator arm 42, and a head slider 44 is mounted to the other end of the suspension 43. The magnetoresistance element 1 shown in FIG. 1 is utilized in a magnetic reproducing head incorporated in the head slider 44. In the particular use shown in FIG. 4, the magnetoresistance element 1 is formed on a nonmagnetic insulating substrate such as an AlTiC (Al₂O₃—TiC) substrate.

Lead wires 45 for writing and reading information are formed on the suspension 43, and these lead wires 45 are electrically connected to the electrodes of the magnetic reproducing head incorporated in the head slider 44. Incidentally, a reference numeral 46 shown in FIG. 4 denotes an electrode pad of the magnetic head assembly 41.

The magnetic head assembly 41 of the construction described above can be mounted to, for example, a magnetic recording-reproducing apparatus described in the following.

FIG. 5 is an oblique view schematically showing a magnetic recording-reproducing apparatus 51 in which the magnetic head assembly 41 shown in FIG. 4 is mounted. In the magnetic recording-reproducing apparatus 51 shown in FIG. 5, a magnetic disk 52, which is a magnetic recording medium, is rotatably supported by a spindle 53. A motor (not shown), which is operated in response to a control signal generated from a control section (not shown), is connected to the spindle 53, with the result that it is possible to control the rotation of the magnetic disk 52.

A fixed axle 54 is arranged in the vicinity of the circumferential portion of the magnetic disk 52. The magnetic head assembly 41 shown in FIG. 4 is swingably supported by the fixed axle 54 via ball bearings (not shown) that are mounted at the upper and lower portions of the fixed axle 54. A coil (not shown) is wound about the bobbin portion of the magnetic head assembly 41. The coil, permanent magnets facing each other with the coil interposed therebetween and a counter yoke collectively form a magnetic circuit and a voice coil motor 55. It is possible for the voice coil motor 55 to permit the head slider 44 at the tip of the magnetic head assembly 41 to be positioned on a desired track of the magnetic disk 52. Incidentally, in the magnetic recording-reproducing apparatus 51, the recording and reproduction of information are carried out under the state that the magnetic disk 52 is rotated so as to cause the head slider 44 to be held floating from the magnetic disk 52.

As described above, the magnetoresistance element 1 according to the present embodiment can be utilized in an MRAM, a magnetic head, a magnetic reproducing apparatus, and a magnetic recording-reproducing apparatus. Incidentally, it is possible for the MRAM to be mounted to various electronic apparatuses such as a portable data terminal including a mobile phone. Also, the magnetoresistance element 1 according to the present embodiment can be utilized in, for example, a magnetic sensor and a magnetic field detector using the magnetic sensor.

Some Examples of the present invention will now be described.

### EXAMPLE 1

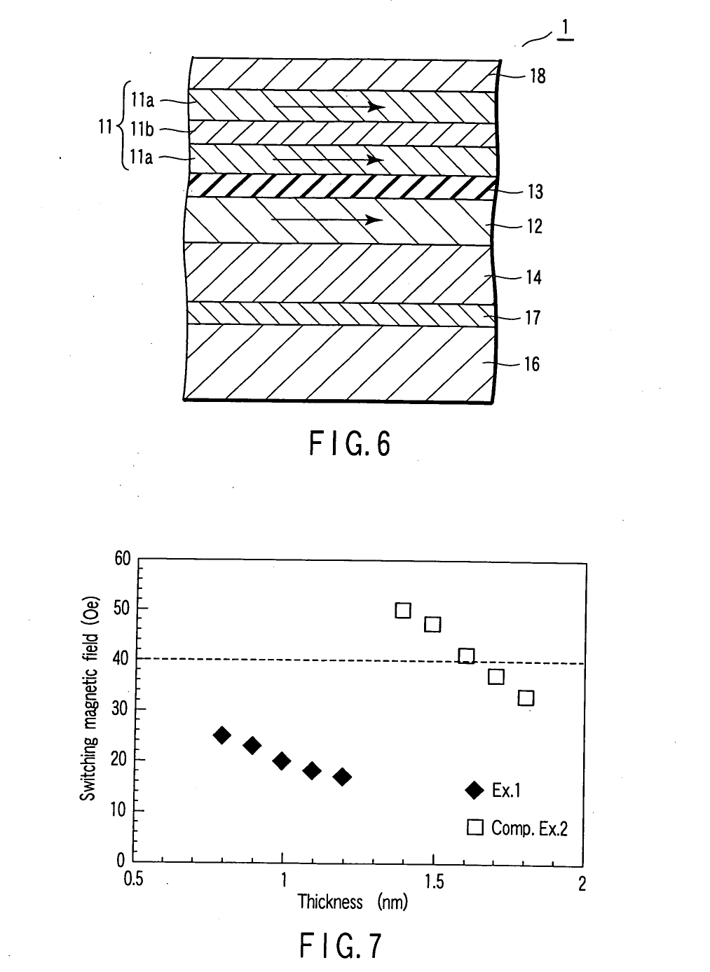

FIG. 6 is a cross-sectional view schematically showing a magnetoresistance element 1 according to Example 1 of the present invention. The magneto-resistance element 1 shown in FIG. 6 is a spin valve type tunnel junction element (MTJ element), particularly, a bottom type ferromagnetic single tunnel junction element in which the pinned layer 12 is arranged on the side of the substrate relative to the free layer 11. Also, in the MTJ element 1 shown in FIG. 6, a pair of ferromagnetic layers 11a are equal to each other in the direction of magnetization.

To be more specific, the MTJ element 1 shown in FIG. 6 has a laminate structure in which a lower electrode 16 made of Ta and having a thickness of 10 nm, an underlayer 17 made of NiFe and having a thickness of 2 nm, an antiferromagnetic layer 14 made of IrMn and having a thickness of 15 nm, a pinned layer 12 made of Co₉₀Fe₁₀ and having a thickness of 3 nm, a nonmagnetic layer 13 made of Al₂O₃ and having a thickness of 1.5 nm, a ferromagnetic layer 11a made of Co₉₀Fe₁₀ and having a thickness of 2 nm, a nonmagnetic film 11b made of Mo, a ferromagnetic layer 11a made of Co₉₀Fe₁₀ and having a thickness of 2 nm, a protective layer 18 made of Ta and having a thickness of 5 nm, and an upper electrode layer (not shown) is formed on a substrate (not shown). Incidentally, the upper electrode layer noted above has a laminate structure including a Ti layer having a thickness of 5 nm and a Au layer formed on the Ti layer and having a thickness of 25 nm. The MTJ element 1 has a rectangular planar shape sized at about 0.5 μm×about 1.5 μm.

In Example 1, the thin films constituting the laminate structure were successively formed within a magnetron sputtering apparatus. For determining the thickness of each thin film, the deposition rate for each thin film was determined in advance, and the thickness of each thin film was controlled by the deposition time calculated from the thickness of the thin film to be formed and the deposition rate determined. Incidentally, for determining the deposition rate for each thin film, thin films having a thickness falling within a range of between 50 nm and 100 nm were actually formed, and the deposition rate was determined from the actually measured thickness of the thin film and the required deposition time. Then, these thin films were patterned into the shape described above. After the patterning the thin films, a heat treatment was applied at 290° C. for one hour in a magnetic field of about 5 kOe. In this fashion, a plurality of MTJ elements 1 differing from each other in the thickness of the nonmagnetic film 11b were manufactured.

### COMPARATIVE EXAMPLE 1

An MTJ element 1 was manufactured by the process equal to that described above in conjunction with Example 1, except that one of the ferromagnetic layers 11a and the nonmagnetic film 11b were omitted. More specifically, in Comparative Example 1, the free layer 11 was formed to have a single layer structure of the ferromagnetic layer 11a made of Co₉₀Fe₁₀ and having a thickness of 2 nm.

### COMPARATIVE EXAMPLE 2

MTJ elements 1 were manufactured by the process equal to that described above in conjunction with Example 1, except that ruthenium was used as the material of the nonmagnetic film 11b. Incidentally, in Comparative Example 2, the MTJ elements 1 were formed to be different from one another in the thickness of the nonmagnetic film 11b. Also, in Comparative Example 2, the thickness of each nonmagnetic film 11b was set to permit the ferromagnetic layers 11a to form a ferromagnetic exchange coupling. It should be noted, however, that, in setting the thickness of the nonmagnetic film 11b, the influences given to the free layer 11 by the layers other than the free layer 11 were neglected.

Next, RH curves for the MTJ elements 1 of Example 1, Comparative Example 1 and Comparative Example 2 were determined by applying an external magnetic field between −500 Oe and +500 Oe along the easy axis of magnetization of the free layer 11, and the switching magnetic field was obtained from these RH curves. FIG. 7 shows the result.

FIG. 7 is a graph showing the switching magnetic field for the MTJ element 1 according to each of Example 1, Comparative Example 1 and Comparative Example 2. In the graph of FIG. 7, the thickness of the nonmagnetic film 11b is plotted on the abscissa, and the switching magnetic field is plotted on the ordinate. Incidentally, the broken line shown in the graph denotes the data obtained from the MTJ element 1 for Comparative Example 1.

As shown in FIG. 7, the switching magnetic field of the MTJ element 1 of Comparative Example 1 was 40 Oe. Also, regarding the MTJ elements 1 of Comparative Example 2, it was certainly possible to make the switching magnetic field weaker than that for the MTJ element 1 of Comparative Example 1 in the case of increasing the thickness of the nonmagnetic film 11b. However, the switching magnetic field for the MTJ element 1 of Comparative Example 2 was stronger than that for the MTJ element 1 of Comparative Example 1 in the case of decreasing the thickness of the nonmagnetic film 11b. On the other hand, regarding the MTJ element 1 of Example 1, it was possible to make the switching magnetic field weaker than that for the MTJ element 1 of Comparative Example 1 not only in the case where the thickness of the nonmagnetic film 11b was increased but also in the case where the thickness of the nonmagnetic film 11b was decreased.

### EXAMPLE 2

MTJ elements 1 were manufactured by the process equal to that described previously in conjunction with Example 1, except that rhenium was used as a material of the nonmagnetic film 11b. Incidentally, in this Example, the MTJ elements 1 were formed to be different from one another in the thickness of the nonmagnetic film 11b and in the thickness of the ferromagnetic layer 11a. Also, in this Example, the thickness of the nonmagnetic film 11b was set to permit the ferromagnetic layers 11a to form a ferromagnetic exchange coupling with each other. However, in setting the thickness of the nonmagnetic film 11b, the influences given to the free layer 11 by the layers other than the free layer 11 were neglected.

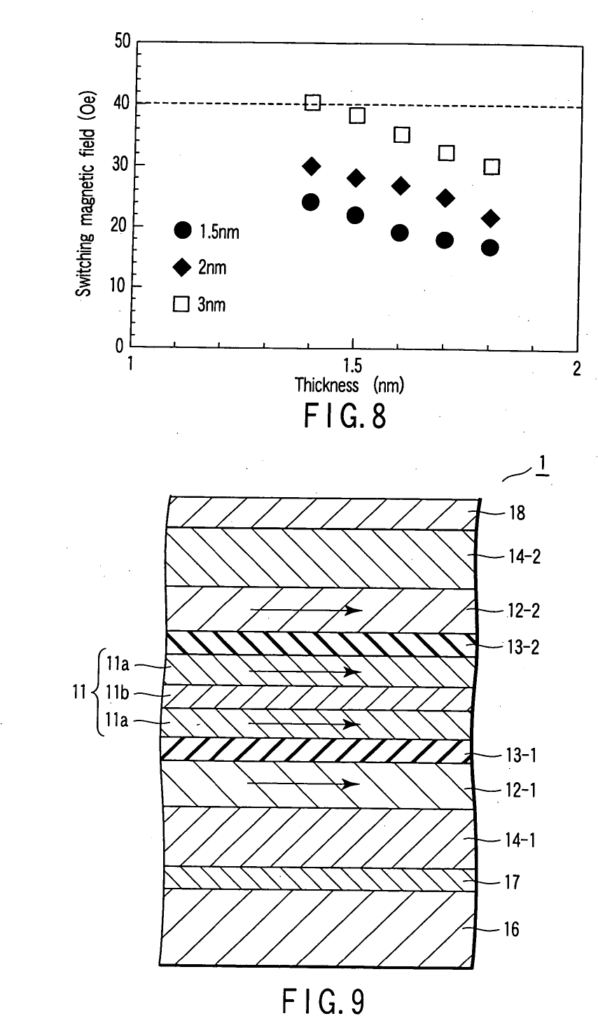

In respect of these MTJ elements 1, the switching magnetic field was measured by the method equal to that described previously. FIG. 8 shows the result.

FIG. 8 is a graph showing the switching magnetic fields for the MTJ elements 1 according to Example 2. In the graph of FIG. 8, the thickness of the nonmagnetic film 11b is plotted on the abscissa, and the switching magnetic field is plotted on the ordinate. Incidentally, the experimental data given in FIG. 8 cover the cases where the thickness of the ferromagnetic layer 11a was set at 1.5 nm, 2 nm or 3 nm. Also, the broken line shown in FIG. 8 denotes the data obtained from the MTJ element 1 of Comparative Example 1.

As shown in FIG. 8, regarding the MTJ elements 1 of Example 2, it was possible to make the intensity of the switching magnetic field equal to or lower than that for the MTJ element 1 of Comparative Example 1 in not only the case where the thickness of the nonmagnetic film 11b was increased but also the case where the thickness of the nonmagnetic film 11b was decreased. Also, regarding the MTJ elements 1 of Example 2, the intensity of the switching magnetic field was lowered with decrease in the thickness of the ferromagnetic layer 11a, as apparent from FIG. 8.

### EXAMPLE 3

FIG. 9 is a cross-sectional view schematically showing the magnetoresistance element according to Example 3 of the present invention. The magneto-resistance element 1 is a spin valve type tunnel junction element (MTJ element), particularly, a ferromagnetic double tunnel junction element in which the free layer 11 was interposed between a pair of pinned layers 12-1 and 12-2. In the MTJ element 1 of this Example, a pair of ferromagnetic layers 11a are equal to each other in the direction of magnetization.

The MTJ element 1 shown in FIG. 9 has a laminate structure in which a lower electrode layer 16 made of Ta and having a thickness of 30 nm, an underlayer 17 made of NiFe and having a thickness of 2 nm, an antiferromagnetic layer 14-1 made of IrMn and having a thickness of 15 nm, a pinned layer 12-1 made of Co₉₀Fe₁₀ and having a thickness of 3 nm, a nonmagnetic layer 13-1 made of Al₂O₃ and having a thickness of 1.2 nm, a ferromagnetic layer 11a made of Co₉₀Fe₁₀ and having a thickness of 2 nm, a nonmagnetic film 11b made of W, a ferromagnetic layer 11a made of Co₉₀Fe₁₀ and having a thickness of 2 nm, a nonmagnetic layer 13-2 made of Al₂O₃ and having a thickness of 1.2 nm, a pinned layer 12-2 made of Co₉₀Fe₁₀ and having a thickness of 2 nm, an antiferromagnetic layer 14-2 made of IrMn and having a thickness of 15 nm, a protective layer 18 made of Ta and having a thickness of 5 nm, and an upper electrode layer (not shown) are formed on a substrate (not shown). Incidentally, the upper electrode layer has a laminate structure that includes a Ti layer having a thickness of 5 nm and a Au layer formed on the Ti layer and having a thickness of 25 nm. Also, the MTJ element 1 had a rectangular planar shape sized at about 0.5 μm×about 1.5 μm.

In this Example, a plurality of MTJ elements 1 differing from one another in the thickness of the nonmagnetic film 11b were manufactured by the process equal to that described previously in conjunction with Example 1, except that the construction described above was employed. Incidentally, in this Example, the thickness of the nonmagnetic film 11b was set to permit the ferromagnetic layers 11a to form a ferromagnetic exchange coupling with each other. However, in setting the thickness of the nonmagnetic film 11b, the influences given to the free layer 11 by the layers other than the free layer 11 were neglected.

### COMPARATIVE EXAMPLE 3

An MTJ element 1 was manufactured by the process equal to that described above in conjunction with Example 3, except that one of the ferromagnetic layers 11a and the nonmagnetic film 11b were omitted. More specifically, in Comparative Example 3, the free layer 11 was formed to have a single layer structure including the ferromagnetic layer 11a alone made of Co₉₀Fe₁₀ and having a thickness of 2 nm.

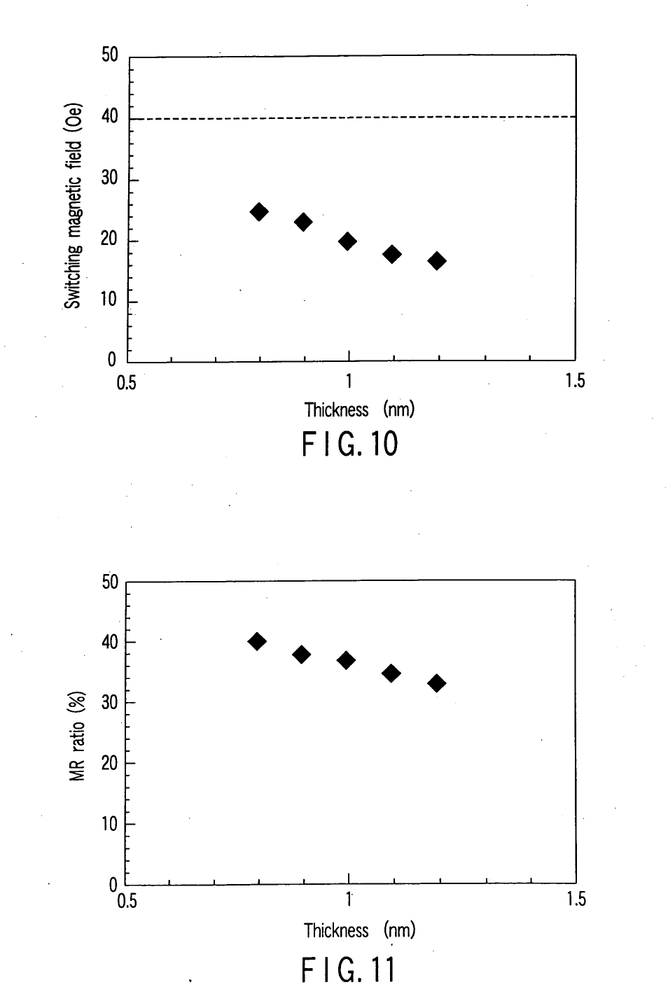

Next, the switching magnetic field was measured for the MTJ element 1 according to each of Example 3 and Comparative Example 3 by the method similar to that described previously. Also, the MR ratio was obtained for the MTJ element 1 of Example 3. FIGS. 10 and 11 show the results.

FIG. 10 is a graph showing the switching magnetic fields for the MTJ elements 1 of Example 3. In the graph of FIG. 10, the thickness of the nonmagnetic film 11b is plotted on the abscissa, and the switching magnetic field is plotted on the ordinate. Incidentally, the broken line shown in FIG. 10 denotes the data obtained from the MTJ element 1 of Comparative Example 3.

As shown in FIG. 10, the switching magnetic field was 40 Oe for the MTJ element 1 of Comparative Example 1. On the other hand, regarding the MTJ element 1 of Example 3, it was possible to make the intensity of the switching magnetic field lower than that for the MTJ element 1 of Comparative Example 3 in not only the case where the thickness of the nonmagnetic film 11b was increased but also the case where the thickness of the nonmagnetic film was decreased.

FIG. 11 is a graph showing the MR ratio of the MTJ element 1 for Example 3 of the present invention. In the graph of FIG. 11, the thickness of the nonmagnetic film 11b is plotted on the abscissa, and the MR ratio is plotted on the ordinate.

As shown in FIG. 11, regarding the MTJ element 1 of Example 3, the MR ratio was increased with decrease in the thickness of the nonmagnetic film 11b. It is considered reasonable to understand that, if the thickness of the nonmagnetic film 11b is small, the electron scattering can be relatively suppressed so as to retain the conduction while preserving the spin, with the result that the MR ratio is increased with decrease in the thickness of the nonmagnetic film 11b.

### EXAMPLE 4

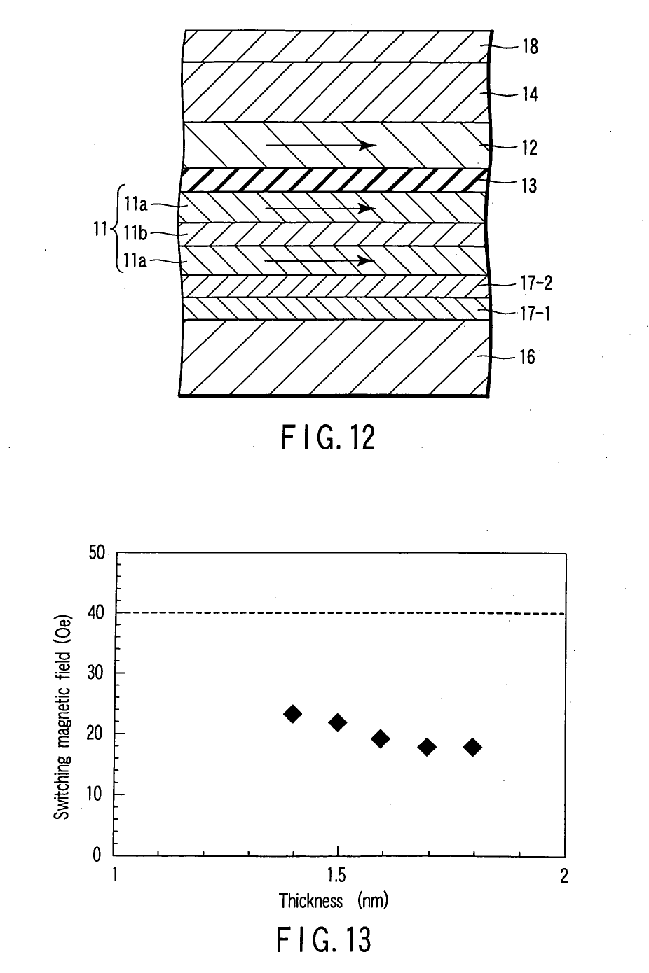

FIG. 12 is a cross-sectional view schematically showing the magnetoresistance element 1 according to Example 4 of the present invention. The magneto-resistance element 1 is a spin valve type tunnel junction element (MTJ element), particularly, a top type ferromagnetic single tunnel junction element in which the free layer 11 is arranged on the substrate side relative to the pinned layer 12. Also, in this MTJ element 1, a pair of ferromagnetic layers 11a are equal to each other in the direction of magnetization.

The MTJ element 1 shown in FIG. 12 has a laminate structure in which a lower electrode layer 16 made of Ta and having a thickness of 30 nm, a first underlayer 17-1 made of NiFe and having a thickness of 2 nm, a second underlayer 17-2 made of Cu and having a thickness of 2 nm, a ferromagnetic layer 11a made of Co₉₀Fe₁₀ and having a thickness of 2 nm, a nonmagnetic film 11b made of Nb, another ferromagnetic layer 11a made of Co₉₀Fe₁₀ and having a thickness of 2 nm, a nonmagnetic layer 13 made of Al₂O₃ and having a thickness of 1.2 nm, a pinned layer made of Co₉₀Fe₁₀ and having a thickness of 3 nm, an antiferromagnetic layer 14 made of IrMn and having a thickness of 15 nm, a protective layer 18 made of Ta and having a thickness of 5 nm, and an upper electrode layer (not shown) are formed on a substrate (not shown). Incidentally, the upper electrode layer noted above has a laminate structure including a Ti layer having a thickness of 5 nm and a Au layer formed on the Ti layer and having a thickness of 25 nm. Also, the MTJ element 1 of the particular construction had a rectangular planar shape sized at about 0.5 μm×about 1.5 μm.

In this Example, a plurality of MTJ elements 1 were formed to be different from one another in the thickness of the nonmagnetic film 11b by the method similar to the method described previously in conjunction with Example 1, except that the MTJ elements 1 of Example 4 were constructed as described above. Incidentally, in this Example, the thickness of the nonmagnetic film 11b was set to permit the ferromagnetic layers 11a to form a ferromagnetic exchange coupling with each other. However, in setting the thickness of the nonmagnetic film 11b, the influences given to the free layer 11 by the layers other than the free layer 11 were neglected.

Then, the switching magnetic field was measured for each of these MTJ elements by the method similar to that described previously. FIG. 13 shows the result.

FIG. 13 is a graph showing the switching magnetic field for the MTJ element 1 according to Example 4 of the present invention. In the graph of FIG. 13, the thickness of the nonmagnetic film 11b is plotted on the abscissa, and the switching magnetic field is plotted on the ordinate. Incidentally, the broken line shown in the graph denotes the data obtained from the MTJ element 1 of Comparative Example 1.

As shown in FIG. 13, regarding the MTJ element 1 of Example 4, it was possible to make the intensity of the switching magnetic field lower than that for the MTJ element 1 of Comparative Example 3 in not only the case where the thickness of the nonmagnetic film 11b was increased but also the case where the thickness of the nonmagnetic film was decreased.

### EXAMPLE 5

MTJ elements 1 were manufactured by the method similar to the method described previously in conjunction with Example 1, except that Si was used as a material of the nonmagnetic film 11b in this Example. Incidentally, in this Example, a plurality of MTJ elements 1 were formed to be different from one another in the thickness of the nonmagnetic film 11b within a range of between 1.4 nm and 1.8 nm. Also, in this Example, the thickness of the nonmagnetic film 11b was set to permit the ferromagnetic layers 11a to form a ferromagnetic exchange coupling with each other. However, in setting the thickness of the nonmagnetic film 11b, the influences given to the free layer 11 by the layers other than the free layer 11 were neglected.

Next, the switching magnetic field was measured for each of these MTJ elements 1 by the method similar to that described previously. As a result, regarding the MTJ element 1 of Example 5, it was found possible to make the intensity of the switching magnetic field lower than that for the MTJ element 1 of Comparative Example 1 in not only the case where the thickness of the nonmagnetic film 11b was increased but also the case where the thickness of the nonmagnetic film was decreased.

### EXAMPLE 6

MTJ elements 1 were manufactured by the method similar to the method described previously in conjunction with Example 3, except that Ge was used as a material of the nonmagnetic film 11b in this Example. Incidentally, in this Example, a plurality of MTJ elements 1 were formed to be different from one another in the thickness of the nonmagnetic film 11b within a range of between 1.4 nm and 1.8 nm. Also, in this Example, the thickness of the nonmagnetic film 11b was set to permit the ferromagnetic layers 11a to form a ferromagnetic exchange coupling with each other. However, in setting the thickness of the nonmagnetic film 11b, the influences given to the free layer 11 by the layers other than the free layer 11 were neglected.

Next, the switching magnetic field was measured for each of these MTJ elements 1 by the method similar to that described previously. As a result, regarding the MTJ element 1 of Example 6, it was found possible to make the intensity of the switching magnetic field lower than that for the MTJ element 1 of Comparative Example 3 in not only the case where the thickness of the nonmagnetic film 11b was increased but also the case where the thickness of the nonmagnetic film was decreased.

### EXAMPLE 7

An MTJ element 1 was manufactured by the method similar to the method described previously in conjunction with Example 3, except that Al₂O₃ was used as a material of the nonmagnetic film 11b in this Example. Incidentally, the thickness of the nonmagnetic film 11b was set at 1.0 nm in this Example.

Next, the switching magnetic field was measured for the MTJ element 1 by the method similar to that described previously. As a result, regarding the MTJ element 1 of Example 7, it was possible to make the intensity of the switching magnetic field lower than that for the MTJ element 1 of Comparative Example 3.

### EXAMPLE 8

MTJ elements 1 were manufactured by the method similar to the method described previously in conjunction with Example 3, except that AlN was used as a material of the nonmagnetic film 11b in this Example. Incidentally, in this Example, a plurality of MTJ elements 1 were formed to be different from one another in the thickness of the nonmagnetic film 11b within a range of between 0.5 nm and 1.5 nm.

Next, the switching magnetic field was measured for each of these MTJ elements 1 by the method similar to that described previously. As a result, regarding the MTJ element 1 of Example 8, it was found possible to make the intensity of the switching magnetic field lower than that for the MTJ element 1 of Comparative Example 3 in not only the case where the thickness of the nonmagnetic film 11b was increased but also the case where the thickness of the nonmagnetic film was decreased. Also, in the MTJ element 1 of Example 8, the switching magnetic field was found to be scarcely dependent on the thickness of the nonmagnetic film 11b and to be substantially constant.

As described above, in the technology, employed is a free layer including a plurality of ferromagnetic layers equal to each other in the direction of magnetization and a nonmagnetic film interposed between the adjacent ferromagnetic layers. Also, the nonmagnetic film is made of a material having a small number of valence electrons or a material that does not have a conduction electron at all. The particular construction makes it possible to reverse the magnetization of the free layer with a relatively weak magnetic field.

Additional advantages and modifications will readily occur to those skilled in the art. Therefore, the present invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetoresistance element comprising:
a free layer comprising a first ferromagnetic layer and a second ferromagnetic layer that face each other and whose magnetization directions are equal to each other and a nonmagnetic film intervening between the first and second ferromagnetic layers, the free layer being changeable in the magnetization directions on applying a magnetic field;
a first pinned layer comprising a third ferromagnetic layer that faces the free layer, the first pinned layer retaining a magnetization direction thereof on applying the magnetic field; and
a first nonmagnetic layer intervening between the free layer and the first pinned layer, the nonmagnetic film being made of a material selected from the group consisting of titanium, vanadium, zirconium, niobium, molybdenum, technetium, hafnium, tungsten, rhenium and alloys thereof.

2. The magnetoresistance element according to claim 1, wherein an average thickness of the nonmagnetic film falls within a range of 0.1 nm to 10 nm.

3. The magnetoresistance element according to claim 1, wherein the nonmagnetic film is made of a material selected from the group consisting of titanium, vanadium, zirconium, niobium, molybdenum, technetium, hafnium, tungsten and alloys thereof.

4. The magnetoresistance element according to claim 1, further comprising:
a second pinned layer comprising a fourth ferromagnetic layer that faces the first pinned layer with the free layer interposed therebetween, the second pinned layer retaining a magnetization direction thereof on applying the magnetic field; and
a second nonmagnetic layer intervening between the free layer and the second pinned layer.

5. A magnetic memory comprising:
a word line;
a bit line intersecting the word line; and
a memory cell positioned in an intersection portion of the word and bit lines and including the magnetoresistance element according to claim 1.

6. A magnetic head comprising:
the magnetoresistance element according to claim 1; and
a support member supporting the magnetoresistance element.

7. A magnetoresistance element comprising:
a free layer comprising a first ferromagnetic layer and a second ferromagnetic layer that face each other and whose magnetization directions are equal to each other and a nonmagnetic film intervening between the first and second ferromagnetic layers, the free layer being changeable in the magnetization directions on applying a magnetic field;
a first pinned layer comprising a third ferromagnetic layer that faces the free layer, the first pinned layer retaining a magnetization direction thereof on applying the magnetic field; and
a first nonmagnetic layer intervening between the free layer and the first pinned layer, a material of the nonmagnetic film being semiconductor or insulator.

8. The magnetoresistance element according to claim 7, wherein an average thickness of the nonmagnetic film falls within a range of 0.1 nm to 10 nm.

9. The magnetoresistance element according to claim 7, further comprising:
a second pinned layer comprising a forth ferromagnetic layer that faces the first pinned layer with the free layer interposed therebetween, the second pinned layer retaining a magnetization direction thereof on applying the magnetic field; and
a second nonmagnetic layer intervening between the free layer and the second pinned layer.

10. A magnetic memory comprising:
a word line;
a bit line intersecting the word line; and
a memory cell positioned in an intersection portion of the word and bit lines and including the magnetoresistance element according to claim 7.

11. A magnetic head comprising:
the magnetoresistance element according to claim 7; and
a support member supporting the magnetoresistance element.

12. A magnetoresistance element comprising:
a free layer comprising a first ferromagnetic layer and a second ferromagnetic layer that face each other and whose magnetization directions are equal to each other and a nonmagnetic film intervening between the first and second ferromagnetic layers, the free layer being changeable in the magnetization directions on applying a magnetic field;
a first pinned layer comprising a third ferromagnetic layer that faces the free layer, the first pinned layer retaining a magnetization direction thereof on applying the magnetic field; and
a first nonmagnetic layer intervening between the free layer and the first pinned layer, the nonmagnetic film containing a material selected from the group consisting of titanium, vanadium, zirconium, niobium, molybdenum, technetium, hafnium, tungsten, rhenium, alloys thereof, semiconductors and insulators.

13. The magnetoresistance element according to claim 12, wherein an average thickness of the nonmagnetic film falls within a range of 0.1 nm to 10 nm.

14. The magnetoresistance element according to claim 12, wherein the nonmagnetic film contains a material selected from the group consisting of titanium, vanadium, zirconium, niobium, molybdenum, technetium, hafnium, tungsten, alloys thereof, semiconductors and insulators.

15. The magnetoresistance element according to claim 12, wherein the nonmagnetic film contains a material selected from the group consisting of titanium, vanadium, zirconium, niobium, molybdenum, technetium, hafnium, tungsten, rhenium and alloys thereof.

16. The magnetoresistance element according to claim 12, wherein the nonmagnetic film contains a semiconductor or an insulator.

17. The magnetoresistance element according to claim 12, further comprising:
a second pinned layer comprising a fourth ferromagnetic layer that faces the first pinned layer with the free layer interposed therebetween, the second pinned layer retaining a magnetization direction thereof on applying the magnetic field; and
a second nonmagnetic layer intervening between the free layer and the second pinned layer.

18. A magnetic memory comprising:
a word line;
a bit line intersecting the word line; and
a memory cell positioned in an intersection portion of the word and bit lines and including the magnetoresistance element according to claim 12.

19. A magnetic head comprising:
the magnetoresistance element according to claim 12; and
a support member supporting the magnetoresistance element.
